(19) United States
(12) Patent Application Publication
(10) Pub. No.: US 2026/0247607 A1
(43) Pub. Date: Aug. 20, 2026

(54) MEMORY, MANUFACTURING METHOD THEREFOR AND ELECTRONIC DEVICE

(71) Applicant: BEIJING SUPERSTRING ACADEMY OF MEMORY TECHNOLOGY, Beijing (CN)

(72) Inventors: Xuezheng AI, Beijing (CN); Xiangsheng WANG, Beijing (CN); Guilei WANG, Beijing (CN); Wenhua GUI, Beijing (CN); Chao ZHAO, Beijing (CN); Jin DAI, Beijing (CN); Wei YU, Beijing (CN)

(21) Appl. No.: 19/164,901

(22) PCT Filed: Apr. 24, 2023
(86) PCT No.: PCT/CN2023/090217

§ 371 Date: Sep. 12, 2025

(30) Foreign Application Priority Data
Mar. 28, 2023 (CN) 202310311145.2

(51) Int. Cl. H10B 12/00

(52) U.S. Cl. CPC H10B 12/482; H10B 12/02

(57) ABSTRACT

The present disclosure relates to the technical field of semiconductors. The present disclosure relates to a memory, a manufacturing method therefor and an electronic device, and is used for improving the performance of the memory. The manufacturing method for the memory comprises the following steps: forming initial first insulation layers (L3) that cover side walls of conductive pattern layers (L111) and side walls of sacrificial pattern layers (L21); forming in a direction perpendicular to a substrate (1) wordline holes (G11) that pass through conductive units (111) and corresponding sacrificial pattern layers (L21); sequentially forming on side walls of the wordline holes (G11) initial semiconductor layers (L6), first dielectric layers (L7), and wordlines (WL) that cover the surfaces of the first dielectric layers (L7) facing away from the initial semiconductor layers (L6) and fill the wordline holes (G11); removing the initial first insulation layers (L3) on the side walls of the sacrificial pattern layers (L21), so as to form first insulation layers (L31); removing the sacrificial pattern layers (L21), so as to expose the initial semiconductor layers (L6) inside the wordline holes (G11) in the sacrificial pattern layers (L21); and etching the initial semiconductor layers (L6), so as to form semiconductor parts respectively located inside the conductive units (111).

### CROSS-REFERENCE TO RELATED APPLICATIONS

This application is a national stage of International Application No. PCT/CN 2023/090217, filed on Apr. 24, 2023, which claims priority to Chinese Patent Application No. 202310311145.2 filed at China National Intellectual Property Administration (CNIPA) on Mar. 28, 2023 and entitled “MEMORY, MANUFACTURING METHOD THEREFOR AND ELECTRONIC DEVICE”. The disclosures of International Application No. PCT/CN 2023/090217 and Chinese Patent Application No. 202310311145.2 are hereby incorporated by reference in their entireties.

### TECHNICAL FIELD

The disclosure relates to the technical field of semiconductors, and in particular to a memory, a method for manufacturing a memory, and an electronic device.

### BACKGROUND

With the development of communication technologies and digital technologies, people continuously pursue products with lower power consumption, lighter weight and better performance. A three-dimensional Dynamic Random Access Memory (3D-DRAM) may have higher integration density and larger storage capacity. At present, performance of 3D-DRAM devices is still improved continuously.

### SUMMARY

Some embodiments of the disclosure provide a method for manufacturing a memory, the method includes the following operations.

Multiple conductive pattern layers and multiple sacrificial pattern layers stacked alternately are formed along a direction perpendicular to a substrate, each of the conductive pattern layers includes a Bit Line (BL) extending along a column direction, and multiple conductive units integrally connected to the BL and arranged at intervals in the column direction; an orthographic projection of each of the conductive pattern layers on the substrate is disposed within an orthographic projection of a respective one of the sacrificial pattern layers on the substrate, and a gap is provided between an outer boundary of the orthographic projection of each of the conductive pattern layers on the substrate and an outer boundary of the orthographic projection of the respective one of the sacrificial pattern layers on the substrate.

Initial first insulation layers each covering sidewalls of a respective one of the conductive pattern layers and sidewalls of a respective one of the sacrificial pattern layers are formed, material of the initial first insulation layer is different from material of the sacrificial pattern layer.

Word Line (WL) holes each penetrating the conductive units and the sacrificial pattern layers corresponding thereto are formed along the direction perpendicular to the substrate; the WL hole in each of the conductive units exposes sidewalls of a respective one of the conductive pattern layers and sidewalls of a respective one of the initial first insulation layers arranged on the same layer as the respective one of the conductive pattern layers, such that each of the conductive units is separated into two independent portions, while exposes a respective one of the sacrificial pattern layers disposed between two adjacent ones of the conductive pattern layers, and the sacrificial pattern layers fully surround respective WL holes.

An initial semiconductor layer, a first dielectric layer, and a WL are sequentially formed on a sidewall of each of the WL holes.

The initial first insulation layers are etched along the direction perpendicular to the substrate in initial first insulation layer areas between two adjacent ones of the conductive units connected to a same BL, to obtain through holes, sidewalls of each of the through holes expose the sacrificial pattern layers, and the initial first insulation layers after being patterned form first insulation layers respectively.

The sacrificial pattern layers in all areas between adjacent ones of the conductive pattern layers are removed from interior of the through holes, to expose the initial semiconductor layers between the adjacent ones of the conductive pattern layers.

The initial semiconductor layers between the adjacent ones of the conductive pattern layers are removed from interior of the through holes, to form multiple semiconductor parts that are independent mutually and correspond to the multiple conductive units respectively.

Areas where the sacrificial pattern layers are removed and areas where the initial semiconductor layers are etched are back-filled with insulation materials respectively.

According to some embodiments, the manufacturing method may further include the following operations before sequentially forming, on the sidewall of each of the WL holes, the initial semiconductor layer, the first dielectric layer, and the WL covering a surface of the first dielectric layer away from the initial semiconductor layer and filling the WL hole.

Contact layers are formed on the sidewalls of the WL holes respectively, each of the contact layers is configured to reduce a contact resistance between a respective one of the conductive units and a respective one of the semiconductor parts, and each of the contact layers is in contact with a respective one of the conductive pattern layers, a respective one of the sacrificial pattern layers and a respective one of the initial first insulation layers simultaneously.

A patterning process is performed on each of the contact layers, to reserve an area in contact with the respective one of the conductive pattern layers.

According to some embodiments, a distance between two etched surfaces of each sacrificial pattern layer that are exposed in the WL hole and opposite to each other in a row direction is a first distance, and a distance between two etched surfaces of ach conductive unit that are exposed in the WL hole is a second distance.

A thickness of the contact layer is less than or equal to half of a difference between the second distance and the first distance.

According to some embodiments, the manufacturing method may further include the following operations before forming the contact layers on the sidewalls of the WL holes respectively. Each of the conductive pattern layers exposed by the WL holes is back-etched.

The operation of performing the patterning process on each of the contact layers, to reserve the area in contact with the respective one of the conductive pattern layers may include the following operations. After forming the contact layers on the sidewalls of the WL holes respectively, contact layers in contact with the initial first insulation layers and the sacrificial pattern layers are removed by dry etching in the WL holes.

According to some embodiments, the operation of forming, along the direction perpendicular to the substrate, the multiple conductive pattern layers and the multiple sacrificial pattern layers stacked alternately may include the following operations. Multiple conductive material layers and multiple sacrificial material layers stacked alternately are formed along the direction perpendicular to the substrate.

A first mask layer is formed above the multiple conductive material layers and the multiple sacrificial material layers, the first mask layer is provided with a first pattern, and the first pattern is configured to define areas where the BL and each of the conductive units are formed.

The multiple conductive material layers and the multiple sacrificial material layers are anisotropically etched, to form multiple trenches each penetrating the conductive material layers and the sacrificial material layers, to transfer the first pattern to the conductive material layers and the sacrificial material layers, to form multiple initial conductive pattern layers and the multiple sacrificial pattern layers stacked alternately.

The first mask layer is removed.

Sidewalls of each of the initial conductive pattern layers are back-etched in a respective one of the trenches by using an isotropic etching process, to form the multiple conductive pattern layers.

According to some embodiments, material of the first insulation layer may be different from the material of the sacrificial pattern layer, and the first insulation layer and the sacrificial pattern layer may have different etching selectivity ratios.

According to some embodiments, material of the first insulation layer may include silicon oxide, and the material of the sacrificial pattern layer may include silicon nitride, aluminum oxide or polysilicon.

According to some embodiments, the manufacturing method may further include the following operations before forming, along the direction perpendicular to the substrate, WL holes each penetrating the conductive units and the sacrificial pattern layers corresponding thereto.

A second mask layer is formed above the initial first insulation layers, the multiple conductive pattern layers and the multiple sacrificial pattern layers, the second mask layer is provided with a first opening pattern, and the first opening pattern is configured to define an area where a storage capacitor is formed.

Portions of the initial first insulation layers and portions of the sacrificial pattern layers are removed based on the first opening pattern, to expose an end of each of the conductive units away from the BL, the ends constitute a first electrode of the storage capacitor.

A dielectric material is deposited on upper and lower surfaces and sidewalls of the first electrode, to form a second dielectric layer.

A conductive material is deposited on a surface of the second dielectric layer away from the first electrode, to form a second electrode of the storage capacitor.

According to some embodiments, the operation of depositing the conductive material on the surface of the second dielectric layer away from the first electrode, to form the second electrode of the storage capacitor may further include the following operations.

The conductive material is deposited on the surface of the second dielectric layer away from the first electrode, to form a second electrode material layer

The second electrode material layer is ground with a top one of the sacrificial pattern layers as a grinding stop layer, and the second mask layer is removed simultaneously, to form the second electrode.

According to some embodiments, the operation of removing the portions of the initial first insulation layers and the portions of the sacrificial pattern layers based on the first opening pattern may include the following operations.

The portions of the initial first insulation layers are removed based on the first opening pattern.

The sacrificial pattern layers are isotropically etched based on the first opening pattern, to remove the sacrificial pattern layers below the first opening pattern.

According to some embodiments, after the second electrode of the storage capacitor is formed, the operation of forming, along the direction perpendicular to the substrate, WL holes each penetrating the conductive units and the sacrificial pattern layers corresponding thereto may include the following operations.

A third mask layer is formed above the second electrode, the initial first insulation layers, the multiple conductive pattern layers and the multiple sacrificial pattern layers, the third mask layer is provided with a second opening pattern, and the second opening pattern is configured to define areas where the WLs are formed.

The multiple conductive pattern layers and the multiple sacrificial pattern layers are etched based on the second opening pattern, to form WL initial accommodation grooves.

The third mask layer is removed.

Surfaces of each of the conductive units exposed in a respective one of the WL initial accommodation grooves are back-etched by using an isotropic etching process, to form a respective one of the WL holes.

According to some embodiments, the operation of removing the initial first insulation layers on sidewalls of the sacrificial pattern layers respectively may include the following operations.

A fourth mask layer is formed above the second electrode, the initial first insulation layers, the multiple conductive pattern layers and the multiple sacrificial pattern layers, the fourth mask layer is provided with a third opening pattern, and the third opening pattern is configured to define areas where the initial first insulation layers are removed.

The initial first insulation layers on sidewalls of the sacrificial pattern layers are removed respectively based on the second opening pattern, to form the through holes, each of the through holes exposes a portion of sidewalls of a respective one of the sacrificial pattern layers and a portion of the surface of the second dielectric layer.

The fourth mask layer is removed.

According to some embodiments, the sacrificial pattern layers may be removed by using an isotropic etching process based on the through holes respectively.

The operation of etching the initial semiconductor layers to form semiconductor parts disposed in the conductive units respectively may include the following operations. Each of the initial semiconductor layers exposed in a respective one of the through holes is isotropically etched by using a respective one of the first dielectric layers as an etching stop layer, to form the semiconductor parts.

According to some embodiments, another aspect of the disclosure provides a memory, the memory includes a substrate and multiple conductive layers stacked at intervals in a direction perpendicular to the substrate. Each of the conductive layers includes a BL extending along a column direction, and multiple conductive units arranged at intervals in the column direction; each of the conductive unit includes a first conductive part integrally connected to the BL, and a second conductive part spaced apart from the first conductive part in a row direction; the row direction and the column direction are parallel to the substrate, and the row direction intersects with the column direction.

The memory further includes multiple WLs, multiple semiconductor parts, multiple first insulation layers, and second insulation layers. Each of the multiple WLs extends along the direction perpendicular to the substrate and is disposed between the first conductive part and the second conductive part corresponding to a respective one of the conductive units, a sidewall of each of the WLs is covered with a first dielectric layer. Each of the multiple semiconductor parts surrounds a respective one of the WLs and is disposed on a surface of a respective one of the first dielectric layers away from the WL and between the first conductive part and the second conductive part corresponding to the respective one of the conductive units. Each of the multiple first insulation layers is disposed in a spacing between two adjacent ones of the conductive units in the column direction, covers corresponding sidewalls of the first conductive part, the second conductive part and a respective one of the semiconductor parts in the row direction, and extends to cover sidewalls of the BL disposed in the spacing. Each of the second insulation layers is disposed on upper and lower surfaces of two adjacent ones of the conductive layers, extends to cover sidewalls of a respective one of the first insulation layers exposed in the spacing, and is connected with the respective one of the first insulation layers to form an integrated structure.

According to some embodiments, the memory may further include contact layers each disposed between a respective one of the semiconductor parts and the first conductive part, and contact layers each disposed between the respective one of the semiconductor parts and the second conductive part, a work function of the contact layer is included between a work function of the conductive unit and a work function of the semiconductor part.

According to some embodiments, material of the contact layer may include titanium, titanium nitride, thallium or thallium nitride, material of each of the first conductive part and the second conductive part may include tungsten, and material of the semiconductor part may be metal oxide semiconductor.

According to some embodiments, another aspect of the disclosure provides an electronic device, the electronic device includes the memory as described in any one of the foregoing embodiments.

Details of one or more embodiments of the disclosure will be given in the following drawings and descriptions. Other features, objects and advantages of the disclosure will become apparent from the description, drawings and claims.

### BRIEF DESCRIPTION OF THE DRAWINGS

In order to explain technical solutions of the embodiments of the disclosure more clearly, the drawings required to be used in descriptions of the embodiments will be briefly introduced below. It is apparent that the drawings described below are only some embodiments of the disclosure. Drawings of other embodiments may also be obtained by those of ordinary skill in the art according to these drawings, without paying any creative work.

FIG. 1 is a schematic flowchart of a method for manufacturing a memory provided in some embodiments.

FIG. 2 is a schematic flowchart of forming conductive pattern layers and sacrificial pattern layers in a method for manufacturing a memory provided in some embodiments.

FIG. 3 is a schematic flowchart of forming first insulation layers in a method for manufacturing a memory provided in some embodiments.

FIG. 4 is a schematic flowchart of forming WL holes in a method for manufacturing a memory provided in some embodiments.

FIG. 5A is a schematic structural diagram of a structure obtained by operation S11 in some embodiments.

FIG. 5B is a schematic cross-sectional diagram of the structure shown in FIG. 5A at a section C1.

FIG. 5C is a schematic cross-sectional diagram of the structure shown in FIG. 5A at a section C2.

FIG. 5D is a schematic cross-sectional diagram of the structure shown in FIG. 5A at a section C3.

FIG. 6A is a schematic structural diagram of a structure obtained by operation S13 in some embodiments.

FIG. 6B is a schematic cross-sectional diagram of the structure shown in FIG. 6A at a section C1.

FIG. 6C is a schematic cross-sectional diagram of the structure shown in FIG. 6A at a section C2.

FIG. 6D is a schematic cross-sectional diagram of the structure shown in FIG. 6A at a section C3.

FIG. 7A is a schematic structural diagram of a structure obtained by operation S14 in some embodiments.

FIG. 7B is a schematic cross-sectional diagram of the structure shown in FIG. 7A at a section C1.

FIG. 7C is a schematic cross-sectional diagram of the structure shown in FIG. 7A at a section C2.

FIG. 7D is a schematic cross-sectional diagram of the structure shown in FIG. 7A at a section C3.

FIG. 8A is a schematic structural diagram of a structure obtained by operation S20 in some embodiments.

FIG. 8B is a schematic cross-sectional diagram of the structure shown in FIG. 8A at a section C1.

FIG. 8C is a schematic cross-sectional diagram of the structure shown in FIG. 8A at a section C2.

FIG. 8D is a schematic cross-sectional diagram of the structure shown in FIG. 8A at a section C3.

FIG. 9A is a schematic structural diagram of a structure obtained by operation S220 in some embodiments.

FIG. 9B is a schematic cross-sectional diagram of the structure shown in FIG. 9A at a section C1.

FIG. 9C is a schematic cross-sectional diagram of the structure shown in FIG. 9A at a section C2.

FIG. 9D is a schematic cross-sectional diagram of the structure shown in FIG. 9A at a section C3.

FIG. 10A is a schematic structural diagram of a structure obtained by operation S240 in some embodiments.

FIG. 10B is a schematic cross-sectional diagram of the structure shown in FIG. 10A at a section C1.

FIG. 10C is a schematic cross-sectional diagram of the structure shown in FIG. 10A at a section C2.

FIG. 10D is a schematic cross-sectional diagram of the structure shown in FIG. 10A at a section C3.

FIG. 11A is a schematic structural diagram of a structure obtained by operation S32 in some embodiments.

FIG. 11B is a schematic cross-sectional diagram of the structure shown in FIG. 11A at a section C1.

FIG. 11C is a schematic cross-sectional diagram of the structure shown in FIG. 11A at a section C2.

FIG. 11D is a schematic cross-sectional diagram of the structure shown in FIG. 11 A at a section C3.

FIG. 12A is a schematic structural diagram of a structure obtained by operation S34 in some embodiments.

FIG. 12B is a schematic cross-sectional diagram of the structure shown in FIG. 12A at a section C1.

FIG. 12C is a schematic cross-sectional diagram of the structure shown in FIG. 12A at a section C2.

FIG. 12D is a schematic cross-sectional diagram of the structure shown in FIG. 12A at a section C3.

FIG. 13A is a schematic structural diagram of a structure obtained by operation S40 in some embodiments.

FIG. 13B is a schematic cross-sectional diagram of the structure shown in FIG. 13A at a section C1.

FIG. 13C is a schematic cross-sectional diagram of the structure shown in FIG. 13A at a section C2.

FIG. 13D is a schematic cross-sectional diagram of the structure shown in FIG. 13A at a section C3.

FIG. 14A is a schematic structural diagram of a structure obtained by operation S52 in some embodiments.

FIG. 14B is a schematic cross-sectional diagram of the structure shown in FIG. 14A at a section C1.

FIG. 14C is a schematic cross-sectional diagram of the structure shown in FIG. 14A at a section C2.

FIG. 14D is a schematic cross-sectional diagram of the structure shown in FIG. 14A at a section C3.

FIG. 15A is a schematic structural diagram of a structure obtained by operation S70 in some embodiments.

FIG. 15B is a schematic cross-sectional diagram of the structure shown in FIG. 15A at a section C1.

FIG. 15C is a schematic cross-sectional diagram of the structure shown in FIG. 15A at a section C2.

FIG. 15D is a schematic cross-sectional diagram of the structure shown in FIG. 15A at a section C3.

FIG. 16A is a schematic structural diagram of a structure obtained by operation S80 in some embodiments.

FIG. 16B is a schematic cross-sectional diagram of the structure shown in FIG. 16A at a section C1.

FIG. 16C is a schematic cross-sectional diagram of the structure shown in FIG. 16A at a section C2.

FIG. 16D is a schematic cross-sectional diagram of the structure shown in FIG. 16A at a section C3.

### DETAILED DESCRIPTION

In order to facilitate understanding the disclosure, the disclosure will be described more completely below with reference to relevant drawings. Embodiments of the disclosure are given in the drawings. However, the disclosure may be implemented in many different forms and is not limited to the embodiments described here. On the contrary, a purpose of providing these embodiments is to make contents disclosed in the disclosure more thorough and comprehensive.

Unless otherwise defined, all technical and scientific terms used here have the same meaning as those usually understood by technicians in the technical field to the disclosure belongs. Here, the terms used in the description of the disclosure are only for the purpose of describing specific embodiments, and are not intended to limit the disclosure.

It should be understood that when an element or layer is referred to as being “on”, “adjacent to”, “connected to” or “coupled to” other elements or layers, the element or layer may be directly on, adjacent to, connected to or coupled to other elements or layers, or there may be elements or layers interposed there-between. On the contrary, when an element is referred to as being “directly on”, “directly adjacent to”, “directly connected to” or “directly coupled to” other elements or layers, there are no element or layer interposed there-between.

Terms of spatial relationships such as “under”, “beneath”, “below”, “underneath”, “above” “upper” or the like may be used here, to describe relationships of an element or feature shown in the drawings to other elements or features. It should be understood that in addition to orientations shown in the drawings, the terms of spatial relationships further include different orientations of a device in use and operation. For example, if the device in the drawings is flipped, an element or feature described as “below other elements” or “underneath other elements” or “under other elements” will be oriented as being “above” other elements or features. Thus, exemplary terms “below” and “under” may include both above and below orientations. Furthermore, the device may also include additional orientations (such as, rotated by 90 degrees or other orientations), and spatial descriptors used here are interpreted correspondingly.

Singular forms “a”, “an” and “said/the” may also include plural forms when they are used here, unless otherwise indicated by the context clearly. It should also be understood that terms “include/contain” or “have” or the like specify presence of stated features, entireties, steps, operations, components, portions or combinations thereof, but do not exclude a possibility of presence or addition of one or more other features, entireties, steps, operations, components, portions or combinations thereof. At the same time, in the description, a term “and/or” includes any and all combinations of relevant listed items.

The embodiments of the disclosure are described here with reference to cross-sectional diagrams that are schematic diagrams of idealized embodiments (and intermediate structures) of the disclosure, such that variations in shapes shown due to for example manufacturing technologies and/or tolerances may be anticipated. Therefore, the embodiments of the disclosure should not be limited to particular shapes of areas shown here, instead, include deviations in shapes due to for example manufacturing technologies. The areas shown in the drawings are substantially schematic, and their shapes do not represent actual shapes of areas of devices, and do not limit the scope of the disclosure.

According to some embodiments, an aspect of the disclosure provides a method for manufacturing a memory, the method is applicable to three-dimensional (3D) stacking of memory units with one or two transistors, and is also applicable to 3D stacking of memory units with or without capacitors. The disclosure is described by taking a memory unit with one transistor and one capacitor as an example.

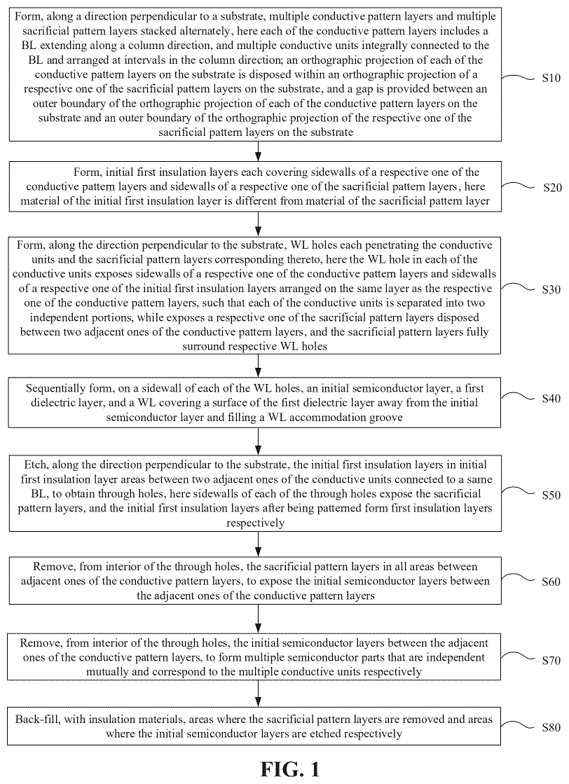

With reference to FIG. 1, a method for manufacturing a memory includes the following operations S10 to S80.

In operation S10, multiple conductive pattern layers and multiple sacrificial pattern layers alternately stacked are formed along a direction perpendicular to a substrate, each of the conductive pattern layers includes a Bit Line (BL) extending along a column direction, and multiple conductive units integrally connected to the BL and arranged at intervals in the column direction; an orthographic projection of each of the conductive pattern layers on the substrate is disposed within an orthographic projection of a respective one of the sacrificial pattern layers on the substrate, and a gap is provided between an outer boundary of the orthographic projection of each of the conductive pattern layers on the substrate and an outer boundary of the orthographic projection of the respective one of the sacrificial pattern layers on the substrate.

In operation S20, initial first insulation layers each covering sidewalls of a respective one of the conductive pattern layers and sidewalls of a respective one of the sacrificial pattern layers are formed, material of the initial first insulation layer is different from material of the sacrificial pattern layer.

In operation S30, word Line (WL) holes each penetrating the conductive units and the sacrificial pattern layers corresponding thereto are formed along the direction perpendicular to the substrate; the WL hole in each of the conductive units exposes sidewalls of a respective one of the conductive pattern layers and sidewalls of a respective one of the initial first insulation layers arranged on the same layer as the respective one of the conductive pattern layers, such that each of the conductive units is separated into two independent portions, while exposes a respective one of the sacrificial pattern layers disposed between two adjacent ones of the conductive pattern layers, and the sacrificial pattern layers fully surround respective WL holes.

In operation S40, an initial semiconductor layer, a first dielectric layer, and a WL are sequentially formed on a sidewall of each of the WL holes.

In operation S50, the initial first insulation layers are etched along the direction perpendicular to the substrate in initial first insulation layer areas between two adjacent ones of the conductive units connected to a same BL, to obtain through holes, sidewalls of each of the through holes expose the sacrificial pattern layers, and the initial first insulation layers after being patterned form first insulation layers respectively.

In operation S60, the sacrificial pattern layers in all areas between adjacent ones of the conductive pattern layers are removed from interior of the through holes, to expose the initial semiconductor layers between the adjacent ones of the conductive pattern layers.

In operation S70, the initial semiconductor layers between the adjacent ones of the conductive pattern layers are removed from interior of the through holes, to form multiple semiconductor parts that are independent mutually and correspond to the multiple conductive units respectively.

In operation S80, areas where the sacrificial pattern layers are removed and areas where the initial semiconductor layers are etched are back-filled with insulation materials respectively.

In the embodiments of the disclosure, a method for removing parasitic transistors in a vertical 3D stacked memory is provided. After multiple conductive pattern layers and multiple sacrificial pattern layers stacked alternately are formed and trenches are etched for the first time, the initial semiconductor layers are back-etched. In this way, the initial semiconductor layer between two adjacent ones of the conductive pattern layers is removed out of the WL holes by using the sacrificial pattern layers subsequently, thereby removing the parasitic transistors. The process is simple, and parasitic capacitances of the transistors in the memory are effectively reduced, thereby improving performance of the memory. At the same time, the channel region and the source/drain region are effectively protected from contamination caused by multiple etchings.

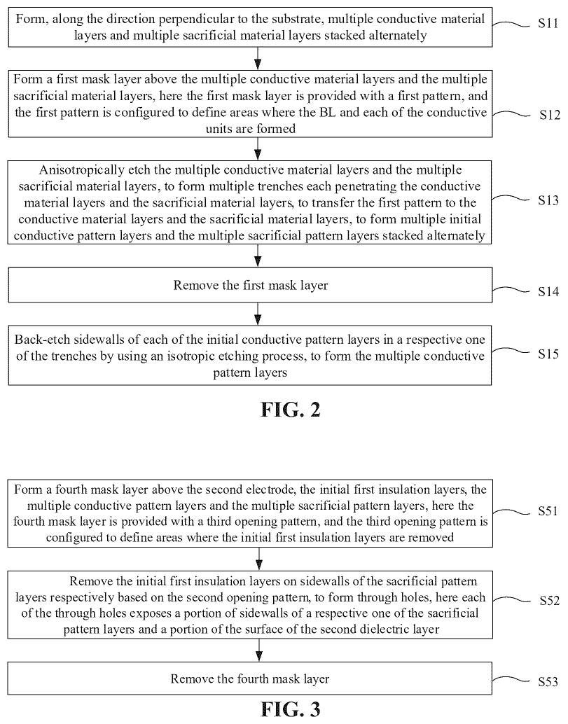

In some embodiments, with reference to FIG. 2, the operation S10 of forming, along the direction perpendicular to the substrate, the multiple conductive pattern layers and the multiple sacrificial pattern layers stacked alternately includes the following operations S11 to S15.

In operation S11, multiple conductive material layers and multiple sacrificial material layers stacked alternately are formed along the direction perpendicular to the substrate.

In operation S12, a first mask layer is formed above the multiple conductive material layers and the multiple sacrificial material layers, the first mask layer is provided with a first pattern, and the first pattern is configured to define areas where the BL and each of the conductive units are formed.

In operation S13, the multiple conductive material layers and the multiple sacrificial material layers are anisotropically etched, to form multiple trenches each penetrating the conductive material layers and the sacrificial material layers, to transfer the first pattern to the conductive material layers and the sacrificial material layers, to form multiple initial conductive pattern layers and the multiple sacrificial pattern layers stacked alternately.

In operation S14, the first mask layer is removed.

In operation S15, sidewalls of each of the initial conductive pattern layers are back-etched in a respective one of the trenches by using an isotropic etching process, to form the multiple conductive pattern layers.

In some embodiments, with reference to FIG. 3, the operation S50 of etching, along the direction perpendicular to the substrate, the initial first insulation layers in initial first insulation layer areas between two adjacent ones of the conductive units connected to a same BL, to obtain through holes includes the following operations S51 to S53.

In operation S51, a fourth mask layer is formed above the second electrode, the initial first insulation layers, the multiple conductive pattern layers and the multiple sacrificial pattern layers, the fourth mask layer is provided with a third opening pattern, and the third opening pattern is configured to define areas where the initial first insulation layers are removed.

In operation S52, the initial first insulation layers on sidewalls of the sacrificial pattern layers are removed respectively based on the second opening pattern, to form the through holes, each of the through holes exposes a portion of sidewalls of a respective one of the sacrificial pattern layers and a portion of the surface of the second dielectric layer.

In operation S53, the fourth mask layer is removed.

In some embodiments, the operation S70 of removing, from interior of the through holes, the initial semiconductor layers between the adjacent ones of the conductive pattern layers, to form a plurality of semiconductor parts that are independent mutually and correspond to the plurality of conductive units respectively includes the following operations. Each of the initial semiconductor layers exposed in a respective one of the through holes is isotropically etched by using a respective one of the first dielectric layers as an etching stop layer, to form the semiconductor parts.

It should be noted that in the above embodiments, the execution order of the operations in the method is not strictly limited, and these operations may not be necessarily performed in the described order, instead, may be performed in other ways. Furthermore, at least a portion of any one of the operations may include multiple sub-operations or multiple stages, these sub-operations or stages are not necessarily performed and completed at the same time, instead, may be performed at different times, and an execution order of these sub-operations or stages is not necessarily a sequential order, instead, may be performed in turn or alternately with other operations or at least a portion of sub-operations or stages of other operations. The method is as long as it is able to implement preparation of a memory corresponding thereto.

Based on this, with respect to the manufacturing methods provided in some of the above embodiments, some methods are provided in some of the following embodiments of the disclosure, as some possible implementations of the above manufacturing methods.

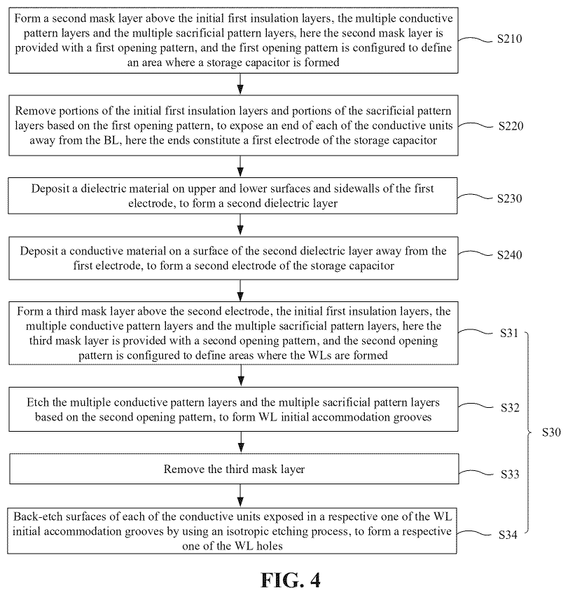

In some embodiments, with reference to FIG. 4, the manufacturing method further includes the following operations S210 to S240 before the operation S30 of forming, along the direction perpendicular to the substrate, WL holes each penetrating the conductive units and the sacrificial pattern layers corresponding thereto.

In operation S210, a second mask layer is formed above the initial first insulation layers, the multiple conductive pattern layers and the multiple sacrificial pattern layers, the second mask layer is provided with a first opening pattern, and the first opening pattern is configured to define an area where a storage capacitor is formed.

In operation S220, portions of the initial first insulation layers and portions of the sacrificial pattern layers are removed based on the first opening pattern, to expose an end of each of the conductive units away from the BL, the ends constitute a first electrode of the storage capacitor.

In operation S230, a dielectric material is deposited on upper and lower surfaces and sidewalls of the first electrode, to form a second dielectric layer.

In operation S240, a conductive material is deposited on a surface of the second dielectric layer away from the first electrode, to form a second electrode of the storage capacitor.

In some embodiments, the operation S220 of removing the portions of the initial first insulation layers and the portions of the sacrificial pattern layers based on the first opening pattern includes the following operations S221 and S222.

In operation S221, the portions of the initial first insulation layers are removed based on the first opening pattern.

In operation S222, the sacrificial pattern layers are isotropically etched based on the first opening pattern, to remove the sacrificial pattern layers below the first opening pattern.

In some embodiments, the operation S240 of depositing the conductive material on the surface of the second dielectric layer away from the first electrode, to form the second electrode of the storage capacitor further includes the following operations S241 and S242.

In operation S241, the conductive material is deposited on the surface of the second dielectric layer away from the first electrode, to form a second electrode material layer.

In operation S242, the second electrode material layer is ground with a top one of the sacrificial pattern layers as a grinding stop layer, and the second mask layer is removed simultaneously, to form the second electrode.

In some embodiments, with continuous reference to FIG. 4, after the operation S240 of forming the second electrode of the storage capacitor, the operation S30 of forming, along the direction perpendicular to the substrate, WL holes each penetrating the conductive units and the sacrificial pattern layers corresponding thereto includes the following operations S31 to S34.

In operation S31, a third mask layer is formed above the second electrode, the initial first insulation layers, the multiple conductive pattern layers and the multiple sacrificial pattern layers, the third mask layer is provided with a second opening pattern, and the second opening pattern is configured to define areas where the WLs are formed.

In operation S32, the multiple conductive pattern layers and the multiple sacrificial pattern layers are etched based on the second opening pattern, to form WL initial accommodation grooves.

In operation S33, the third mask layer is removed.

In operation S34, surfaces of each of the conductive units exposed in a respective one of the WL initial accommodation grooves are back-etched by using an isotropic etching process, to form a respective one of the WL holes.

In some embodiments, a shape of an orthographic projection of each of the WL holes on the substrate includes a rectangular shape. Two opposite sidewalls of each of the WL holes in the column direction expose a respective one of the initial first insulation layers. The manufacturing method further includes the following operations before the operation S40 of sequentially forming, on the sidewall of each of the WL holes, the initial semiconductor layer, the first dielectric layer, and the WL covering a surface of the first dielectric layer away from the initial semiconductor layer and filling the WL hole. Contact layers are formed on the sidewalls of the WL holes respectively, each of the contact layers is configured to reduce a contact resistance between a respective one of the conductive units and a respective one of the semiconductor parts, and each of the contact layers is in contact with a respective one of the conductive pattern layers, a respective one of the sacrificial pattern layers and a respective one of the initial first insulation layers simultaneously. A patterning process is performed on each of the contact layers, to reserve an area in contact with the respective one of the conductive pattern layers.

In some embodiments of the disclosure, before the initial semiconductor layers are formed, contact layers are formed on two etched surfaces each conductive unit that are exposed in the WL hole. In this way, the contact layers may be selectively reserved between the WL holes and the multiple conductive pattern layer, such that the contact layers may be used as contact structures between the semiconductor parts and the conductive units, to effectively reduce a contact resistance of the memory, thereby further improving performance of the memory.

In some embodiments of the disclosure, the manufacturing method further includes the following operations before forming the contact layers on the sidewalls of the WL holes respectively. Each of the conductive pattern layers exposed by the WL holes is back-etched.

The operation of performing the patterning process on each of the contact layers, to reserve the area in contact with the respective one of the conductive pattern layers includes the following operations. After forming the contact layers on the sidewalls of the WL holes respectively, contact layers in contact with the initial first insulation layers and the sacrificial pattern layers are removed by dry etching in the WL holes.

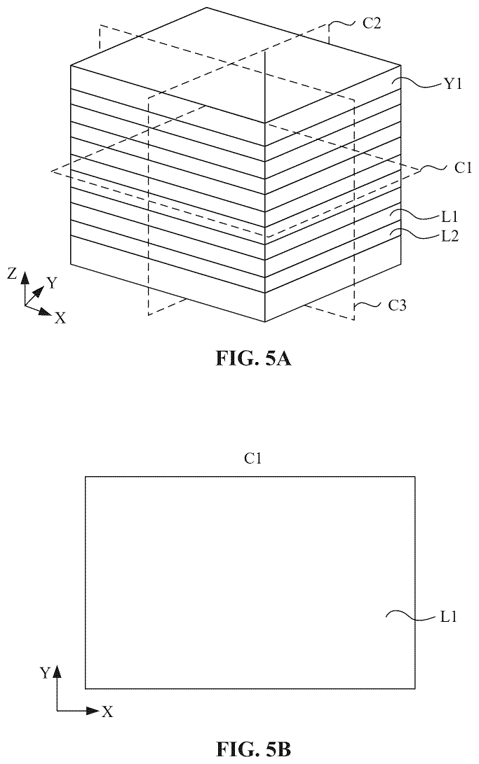

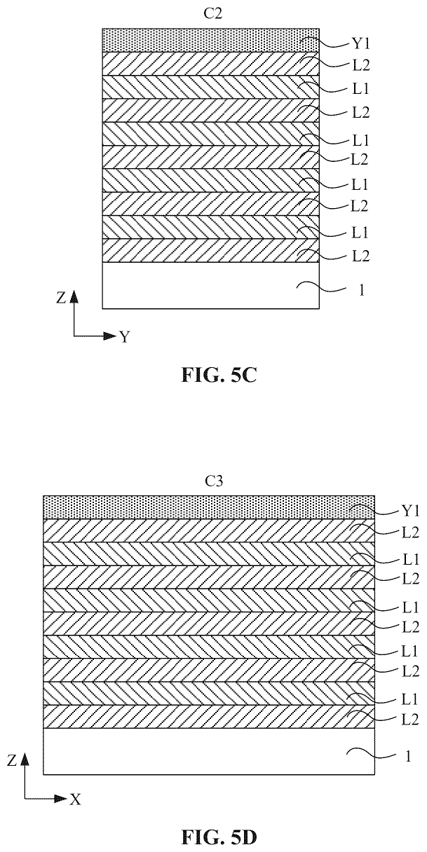

In order to explain the manufacturing method provided in the above embodiments more clearly, the manufacturing method will be described in detail below with reference to FIG. 5A to FIG. 16D.

In some embodiments, with reference to FIG. 2, the operation S10 of forming, along the direction perpendicular to the substrate, the multiple conductive pattern layers and the multiple sacrificial pattern layers stacked alternately includes the following operations S11 to S15.

In operation S11, with reference to FIG. 5A and FIG. 5B, FIG. 5C and FIG. 5D, multiple conductive material layers L1 and multiple sacrificial material layers L2 stacked alternately are formed along the direction perpendicular to the substrate 1 (such as a Z direction).

Exemplarily, the substrate 1 may be made of a semiconductor material, an insulation material, a conductor material, or any combination of material types thereof. The substrate 1 may be a single-layer structure or a multi-layer structure. For example, the substrate 1 may be for example a silicon (Si) substrate, a silicon germanium (SiGe) substrate, a silicon germanium carbon (SiGeC) substrate, a silicon carbide (SiC) substrate, a gallium arsenide (GaAs) substrate, an indium arsenide (InAs) substrate, an indium phosphide (InP) substrate, or other III/V semiconductor substrates or II/VI semiconductor substrates. Or, for another example, the substrate 1 may be a layer-shaped substrate including for example a stack of layers of of Si and SiGe, a stack of layers of of Si and SiC, a silicon on insulator (SOI), or a silicon germanium on insulator, etc.

Exemplarily, the conductive material layer L1 includes a metal layer, such as a tungsten layer.

Exemplarily, the sacrificial material layer L2 includes, but is not limited to a silicon nitride layer. In this way, a structure of alternately stacking the conductive material layers L1 and the sacrificial material layers L2 (such as silicon nitride layers) may effectively adjust a stress problem between multiple layers of the structure, thereby further improving performance of the memory.

Specifically, compared to an embodiment in which the sacrificial material layer L2 is made of silicon oxide, the sacrificial material layer L2 is made of silicon nitride, which may adjust a stress between the sacrificial material layer L2 and the conductive material layer L1 (such as the metal layer) to ensure high film qualities of the conductive material layer L1 and the sacrificial material layer L2.

Specifically, during the process, a stress matching degree between the silicon nitride and the conductive material layer L1 may be controlled by doping in the silicon nitride or controlling a ratio of nitrogen to silicon.

Here, a layer number of stacking of the conductive material layers L1 may be set according to a layer number of stacking of storage layers in the memory. Furthermore, the sacrificial material layers L2 may be disposed between adjacent ones of the conductive layers L1 or at a side of each of first and last ones of the conductive material layers L1, and a layer number of the sacrificial material layers L2 may be set to match the layer number of stacking of the conductive material layers L1. Each of the conductive material layers L1 and each of the sacrificial material layers L2 may be formed by a deposition process respectively.

Furthermore, after the multiple conductive layers L1 and the multiple first sacrificial layers L2 stacked alternately are formed, a first mask material layer Y1 such as a photoresist layer and/or a hard mask layer, may be formed on an upper surface of a top one of the first sacrificial layers L2.

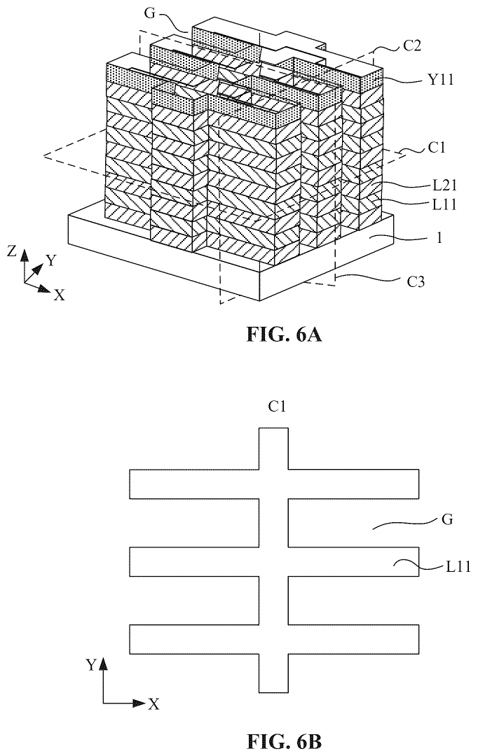

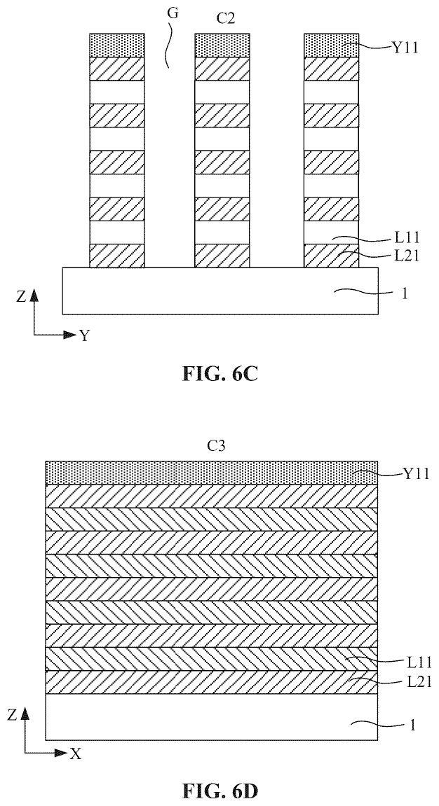

In operation S12, with reference to FIG. 6A and FIG. 6B, FIG. 6C and FIG. 6D, a first mask layer Y11 is formed above the multiple conductive material layers L1 and the multiple sacrificial material layers L2, the first mask layer is provided with a first pattern, and the first pattern is configured to define areas where the BL and each of the conductive units are formed.

In some examples, the operation of forming the first mask layer Y11 above the multiple conductive material layers L1 and the multiple sacrificial material layers L2 includes the following operations. The first mask material layer Y1 is patterned to form the first mask layer Y11.

In operation S13, with continuous reference to FIG. 6A and FIG. 6B, FIG. 6C and FIG. 6D, the multiple conductive material layers L1 and the multiple sacrificial material layers L2 are anisotropically etched, to form multiple trenches G each penetrating the conductive material layers L1 and the sacrificial material layers L2, to transfer the first pattern to the conductive material layers L1 and the sacrificial material layers L2, to form multiple initial conductive pattern layers L11 and the multiple sacrificial pattern layers L21 stacked alternately.

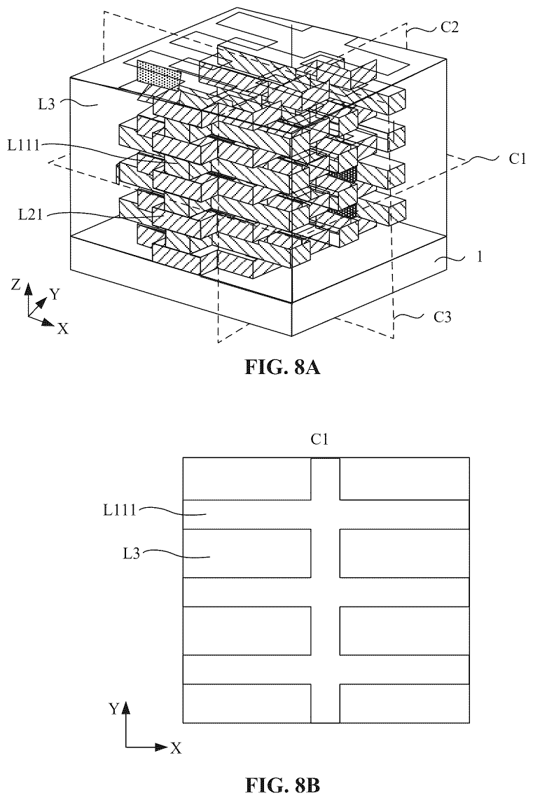

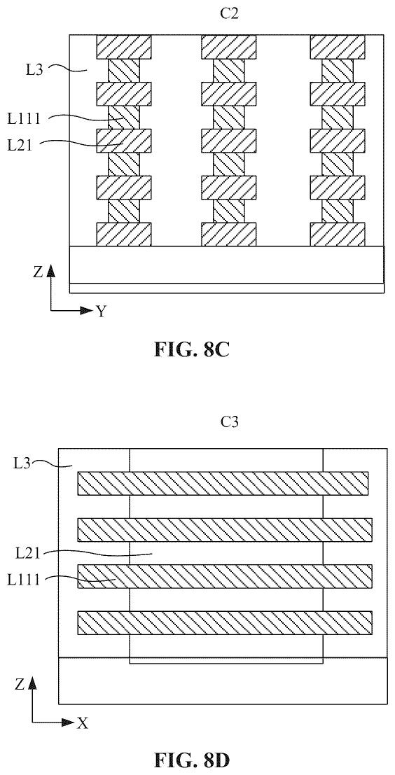

Exemplarily, the initial conductive pattern layer L11 and the sacrificial pattern layer L21 may be formed by etching based on a pattern of the first mask layer Y11, to have the same pattern, such as that shown in FIG. 8B.

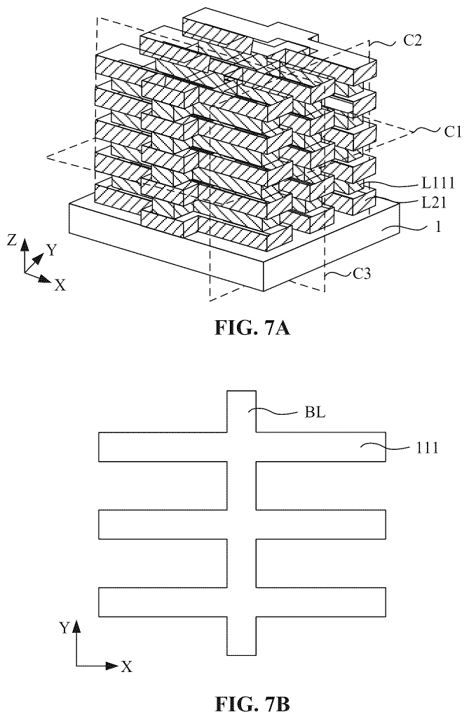

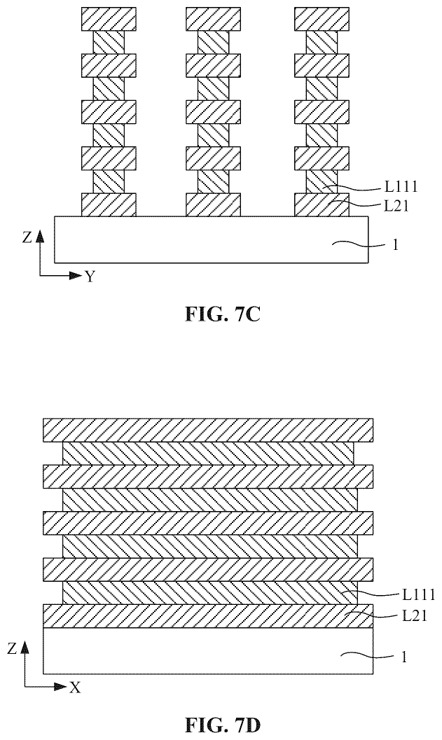

In operation S14, with reference to FIG. 7A and FIG. 7BA, FIG. 7C and FIG. 7D, the first mask layer Y11 is removed.

Exemplarily, the first mask layer Y11 may be removed by using a grinding process, to ensure that a surface of a top one of the sacrificial pattern layers L21 is flat. The grinding process includes, but is not limited to Chemical Mechanical Polishing (abbreviated as CMP).

In operation S15, with reference to FIG. 7A and FIG. 7B, FIG. 7C and FIG. 7D, sidewalls of each of the initial conductive pattern layers L11 are back-etched in a respective one of the trenches G by using an isotropic etching process, to form the multiple conductive pattern layers L111.

Here, with reference to FIG. 7B, each of the conductive pattern layers L111 includes a BL extending along a column direction (such as a Y direction), and multiple conductive units 111 integrally connected to the BL and arranged at intervals in the column direction; the conductive units 111 extend along an X direction respectively and are arranged at intervals along the Y direction. Furthermore, optionally, each of the conductive units 111 is symmetrically distributed with the BL as a center.

Furthermore, an orthographic projection of each of the conductive pattern layers L111 on the substrate 1 is disposed within an orthographic projection of a respective one of the sacrificial pattern layers L21 on the substrate 1, and a gap is provided between an outer boundary of the orthographic projection of each of the conductive pattern layers L111 on the substrate 1 and an outer boundary of the orthographic projection of the respective one of the sacrificial pattern layers L21 on the substrate 1.

In operation S20, with reference to FIG. 8A and FIG. 8B, FIG. 8C and FIG. 8D, initial first insulation layers L3 each covering sidewalls of a respective one of the conductive pattern layers L111 and sidewalls of a respective one of the sacrificial pattern layers L21 are formed, material of the initial first insulation layer is different from material of the sacrificial pattern layer.

Exemplarily, the material of the initial first insulation layer L3 includes, but is not limited to an oxide, such as a material with a low dielectric constant K, such as silicon oxide, etc.

Exemplarily, each of the initial first insulation layers L3 is formed by a deposition process.

Exemplarily, deposition processes mentioned above and below include, but are not limited to an Atomic Layer Deposition (abbreviated as ALD) process, a Chemical Vapor Deposition (abbreviated as CVD) process, a Molecular Layer Deposition (abbreviated as MLD) process, etc.

In operation S30, with reference to FIG. 4, the manufacturing method further includes the following operations S210 to S240 before the operation S30 of forming, along the direction perpendicular to the substrate, WL holes each penetrating the conductive units and the sacrificial pattern layers corresponding thereto.

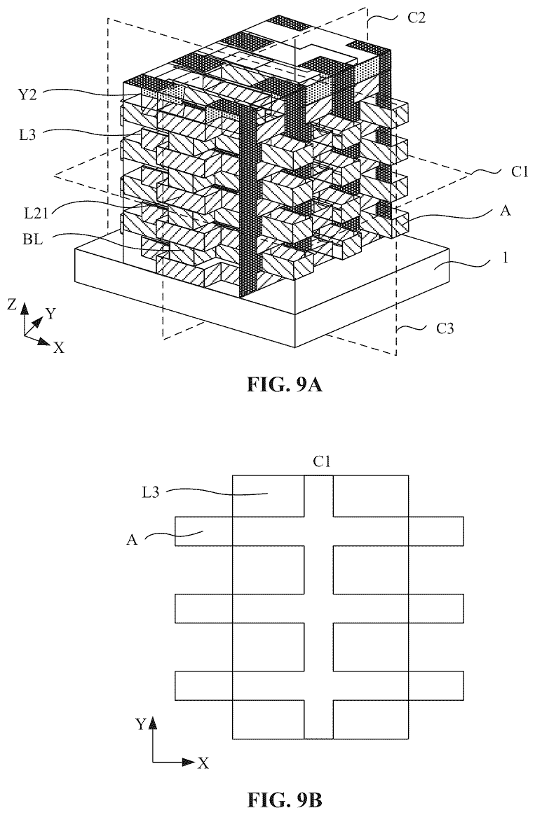

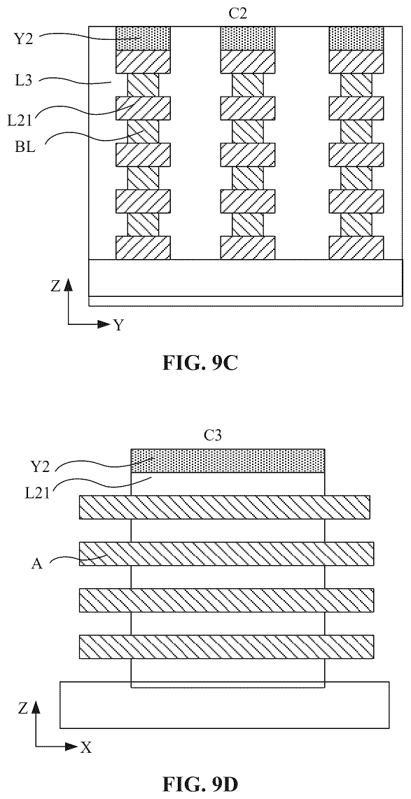

In operation S210, with reference to FIG. 9A and FIG. 9B, FIG. 9C and FIG. 9D, a second mask layer Y2 is formed above the initial first insulation layers L3, the multiple conductive pattern layers L111 and the multiple sacrificial pattern layers L21, the second mask layer Y2 is provided with a first opening pattern, and the first opening pattern is configured to define an area where a storage capacitor is formed.

In operation S220, with continuous reference to FIG. 9A and FIG. 9B, FIG. 9C and FIG. 9D, portions of the initial first insulation layers L3 and portions of the sacrificial pattern layers L21 are removed based on the first opening pattern, to expose an end of each of the conductive units 111 away from the BL, the ends constitute a first electrode A of the storage capacitor.

In some embodiments, the operation S220 of removing the portions of the initial first insulation layers L3 and the portions of the sacrificial pattern layers L21 based on the first opening pattern includes the following operations. The portions of the initial first insulation layers L3 are removed based on the first opening pattern. The sacrificial pattern layers L21 are isotropically etched based on the first opening pattern, to remove the sacrificial pattern layers L21 below the first opening pattern.

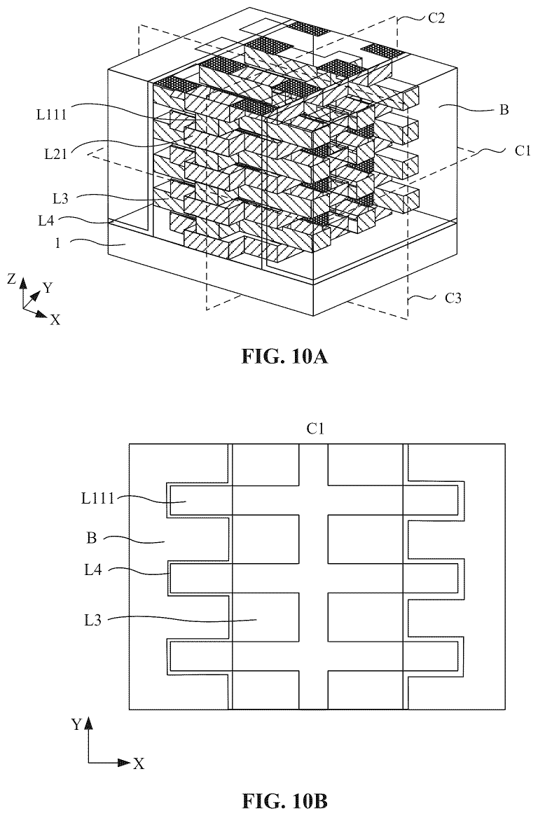

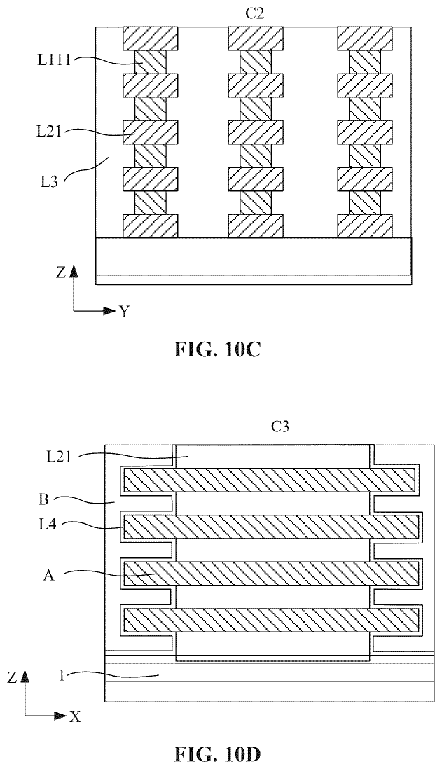

In operation S230, with reference to FIG. 10A and FIG. 10B, FIG. 10C and FIG. 10D, a dielectric material is deposited on upper and lower surfaces and sidewalls of the first electrode A, to form a second dielectric layer L4.

Exemplarily, the second dielectric layer LA includes, but is not limited to a high-K (HK) dielectric layer. The HK dielectric layer refers to a dielectric layer with a high dielectric constant K, and the high dielectric constant K is for example greater than 3.9.

In operation S240, with continuous reference to FIG. 10A and FIG. 10B, FIG. 10C and FIG. 10D, a conductive material is deposited on a surface of the second dielectric layer L4 away from the first electrode A, to form a second electrode B of the storage capacitor.

Exemplarily, material of the second electrode B includes, but is not limited to polysilicon.

Exemplarily, after the second electrode B is formed by using a deposition process, an upper surface of the second electrode B may be ground by using a CMP process.

In some embodiments, the operation S240 of depositing the conductive material on the surface of the second dielectric layer LA away from the first electrode A, to form the second electrode B of the storage capacitor further includes the following operations. The conductive material is deposited on the surface of the second dielectric layer LA away from the first electrode A, to form a second electrode material layer (not shown). The second electrode material layer is ground with a top one of the sacrificial pattern layers as a grinding stop layer, and the second mask layer Y2 is removed simultaneously, to form the second electrode B.

In some embodiments, with continuous reference to FIG. 4, after the operation S240 of forming the second electrode of the storage capacitor, the operation of forming, along the direction perpendicular to the substrate, WL holes each penetrating the conductive units and the sacrificial pattern layers corresponding thereto includes the following operations S31 to S34.

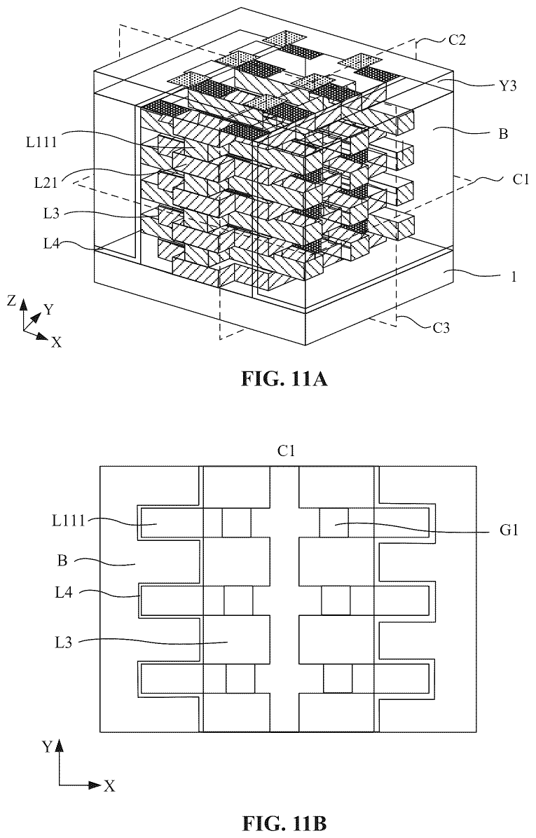

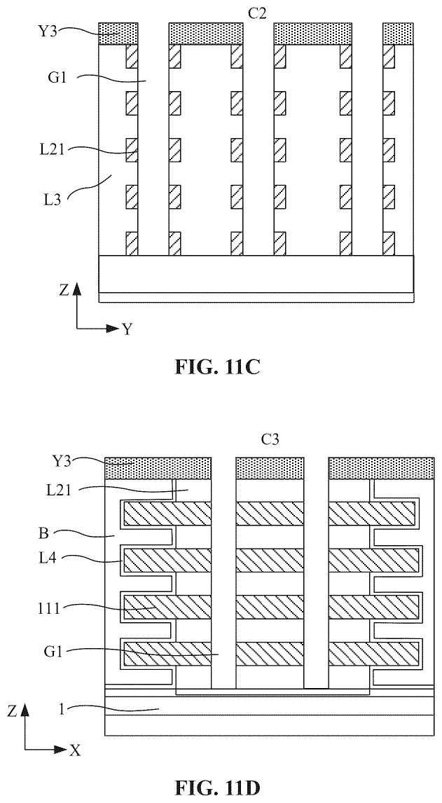

In operation S31, with reference to FIG. 11A and FIG. 11B, FIG. 11C and FIG. 11D, a third mask layer Y3 is formed above the second electrode B, the initial first insulation layers L3, the multiple conductive pattern layers L111 and the multiple sacrificial pattern layers L21, the third mask layer is provided with a second opening pattern, and the second opening pattern is configured to define areas where the WLs are formed.

In operation S32, with continuous reference to FIG. 11A and FIG. 11B, FIG. 11C and FIG. 11D, the multiple conductive pattern layers L111 and the multiple sacrificial pattern layers L21 are etched based on the second opening pattern, to form WL initial accommodation grooves G1.

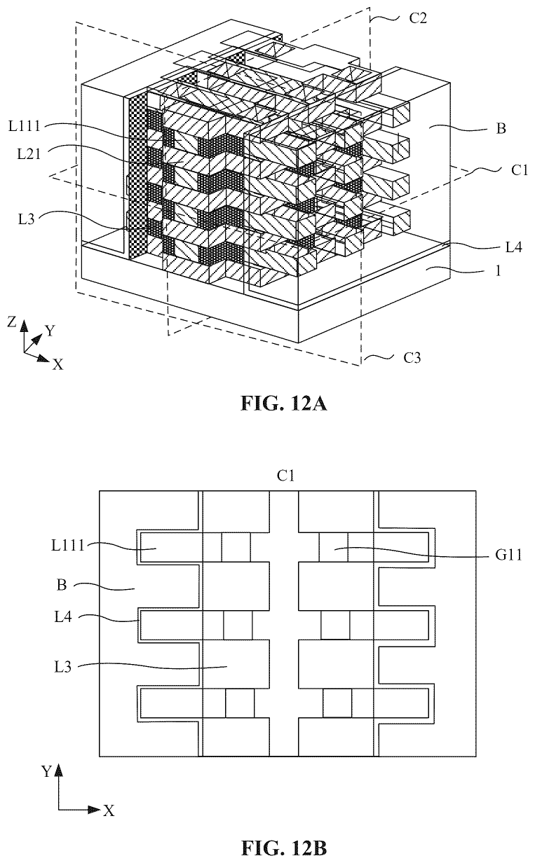

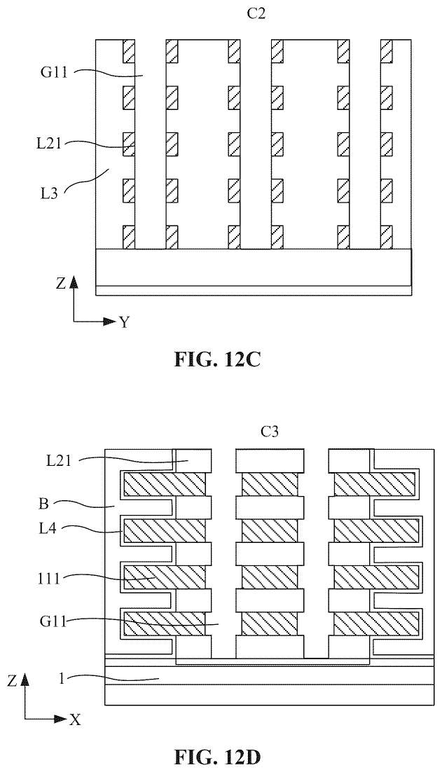

In operation S33, with reference to FIG. 12A and FIG. 12B, FIG. 12C and FIG. 12D, the third mask layer Y3 is removed.

In operation S34, with continuous reference to FIG. 12A and FIG. 12B, FIG. 12C and FIG. 12D, surfaces of each of the conductive units 111 exposed in a respective one of the WL initial accommodation grooves G1 are back-etched by using an isotropic etching process, to form a respective one of the WL holes G11.

In some embodiments, a shape of an orthographic projection of each of the WL holes G11 on the substrate 1 includes a rectangular shape; two opposite sidewalls of each of the WL holes G11 in the column direction (such as the Y direction) expose a respective one of the initial first insulation layers L3.

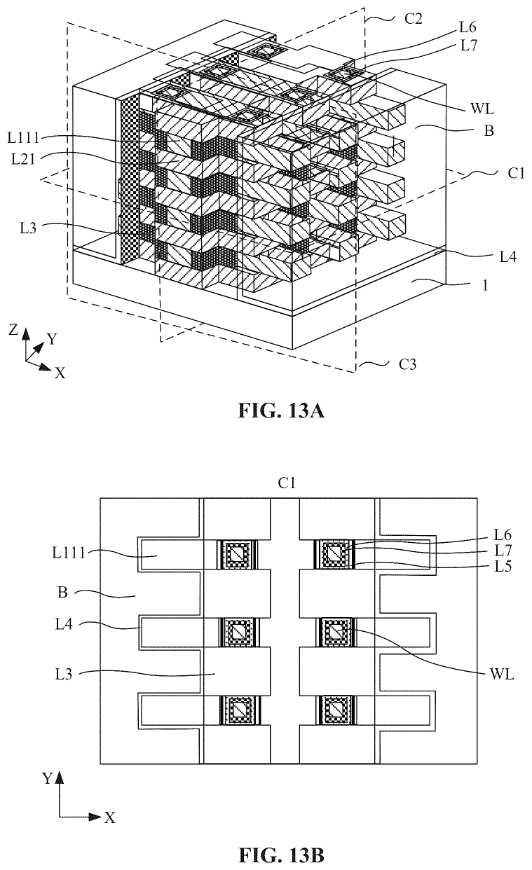

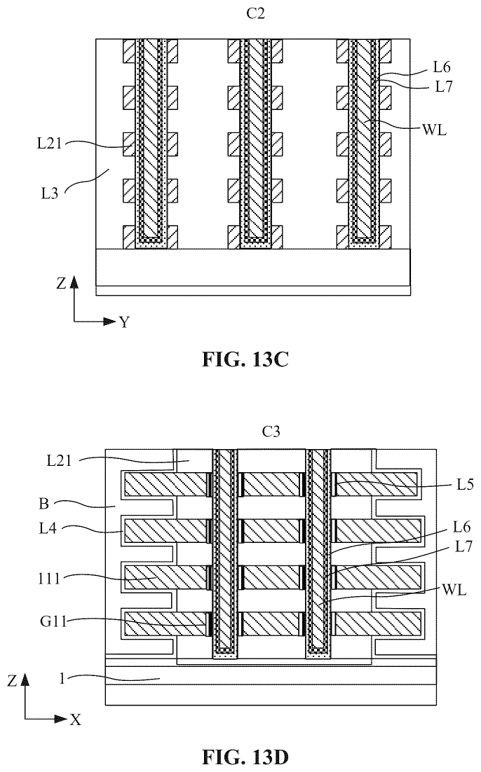

With reference to FIG. 13A and FIG. 13B, FIG. 13C and FIG. 13D, the manufacturing method further includes the following operations before the operation S40 of sequentially forming, on the sidewall of each of the WL holes G11, the initial semiconductor layer L6, the first dielectric layer L7, and the WL covering a surface of the first dielectric layer L7 away from the initial semiconductor layer L6 and filling the WL hole G11.

Contact layers L5 are formed on two etched surfaces of each conductive unit 111 that are exposed the WL hole G11. Here, the WL may be used as a gate WL, that is, the WL may be used as a WL of the memory while may also be used as a gate of a transistor in each corresponding memory unit, thereby controlling on and off of the transistor.

Exemplarily, material of the WL includes a metal, such as tungsten, or copper, etc.

Exemplarily, the contact layers L5 include, but are not limited to nitride layers, such as titanium nitride layers. In this way, the contact layers L5 are formed on two etched surfaces of the conductive unit 111 that are exposed in the WL hole G11, and the contact layers L5 (such as the titanium nitride layers) are used as contact structures between the WL holes G11 and the multiple conductive pattern layers L111, to effectively reduce a contact resistance of the memory, thereby further improving performance of the memory.

The initial semiconductor layer L6 is formed on surfaces of the contact layer L5, the initial first insulation layer L3 and the sacrificial pattern layer L21 exposed in the WL hole G11.

Exemplarily, the initial semiconductor layer L6 includes, but is not limited to metal oxide semiconductor layer.

It may be understood that material of the metal oxide semiconductor layer may be an Indium Gallium Zinc Oxide (IGZO). When material of the metal oxide is IGZO, the transistor has a small leakage current (the leakage current is less than or equal to 10a to 15a), thereby ensuring a low refresh rate of a dynamic memory.

It should be noted that the material of the metal oxide may also be a material such as Indium Tin Oxide (ITO), Indium Tungsten Oxide (IWO), ZnOₓ, InOₓ, In₂O₃, InWO, SnO₂, TiOₓ, InSnOₓ, ZnₓO_{y}N_{z}, MgₓZn_{y}O_{z}, InₓZn_{y}O_{z}, InₓGa_{y}Zn_{z}Oₐ, ZrₓIn_{y}Zn_{z}Oₐ, HfₓIn_{y}Zn_{z}Oₐ, SnₓIn_{y}Zn_{z}Oₐ, AlₓSn_{y}In_{z}ZnₐO_{d}, SiₓIn_{y}Zn_{z}Oₐ, ZnₓSn_{y}O_{z}, AlₓZn_{y}Sn_{z}Oₐ, GaₓZn_{y}Sn_{z}Oₐ, ZrₓZn_{y}Sn_{z}Oₐ, InGaSiO or the like, as long as it ensures that the leakage current of the transistor meets requirements, the material may be specifically adjusted according to an actual situation.

Exemplarily, the initial semiconductor layer L6 may be formed by using a deposition process such as an ALD process.

Exemplarily, the first dielectric layer L7 includes, but is not limited to a HK dielectric layer. The HK dielectric layer refers to a dielectric layer with a high dielectric constant K, and the high dielectric constant K is for example greater than 3.9.

According to some embodiments, a distance between two etched surfaces of each sacrificial pattern layer L21 that are exposed in the WL hole G11 and opposite to each other in a row direction (such as an X direction) is a first distance, and a distance between two etched surfaces of each conductive unit 111 that are exposed in the WL hole G11 is a second distance.

A thickness of the contact layer L5 is less than or equal to half of a difference between the second distance and the first distance

In some embodiments, with reference to FIG. 3, the operation S50 of removing the initial first insulation layers L3 on sidewalls of the sacrificial pattern layers L21 respectively includes the following operations S51 to S53.

In operation S51, a fourth mask layer is formed above the second electrode, the initial first insulation layers, the multiple conductive pattern layers and the multiple sacrificial pattern layers, the fourth mask layer is provided with a third opening pattern, and the third opening pattern is configured to define areas where the initial first insulation layers are removed.

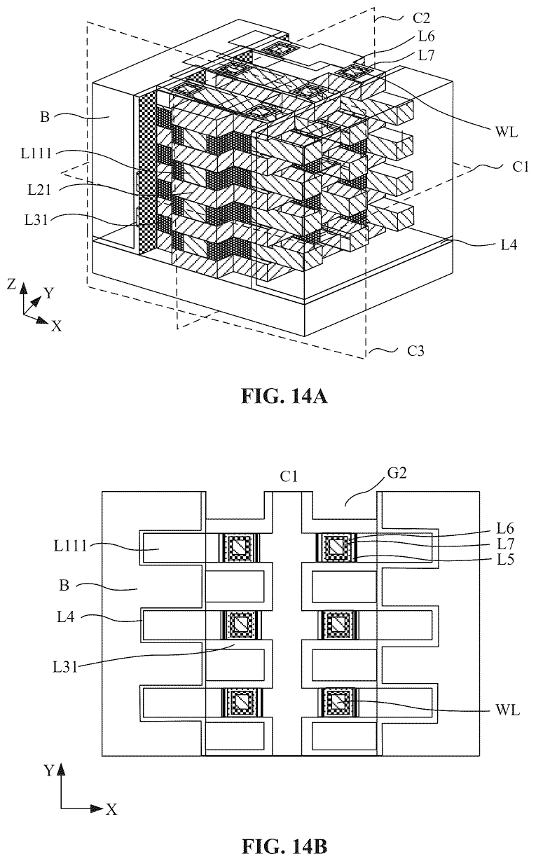

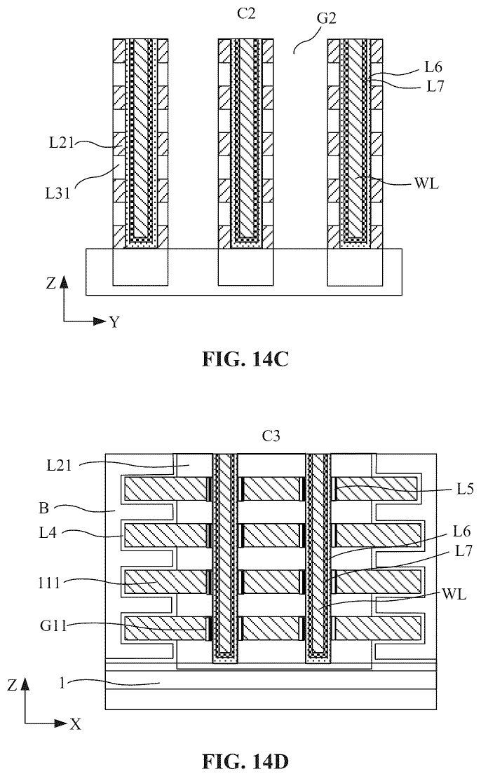

In some examples, with reference to FIG. 14A and FIG. 14B, FIG. 14C and FIG. 14D, a fourth mask layer (not shown) is formed above the second electrode B, the initial first insulation layers L3, the multiple conductive pattern layers L111 and the multiple sacrificial pattern layers L21, the fourth mask layer is provided with a third opening pattern, and the third opening pattern is configured to define areas where the initial first insulation layers L3 are removed.

In operation S52, the initial first insulation layers on sidewalls of the sacrificial pattern layers are removed respectively based on the second opening pattern, to form the through holes G2, each of the through holes G2 exposes a portion of sidewalls of a respective one of the sacrificial pattern layers L21 and a portion of the surface of the second dielectric layer LA.

In some examples, with continuous reference to FIG. 14A and FIG. 14B, FIG. 14C and FIG. 14D, the initial first insulation layers L3 on sidewalls of the sacrificial pattern layers L21 are removed respectively based on the second opening pattern, to form the through holes G2, each of the through holes G2 exposes a portion of sidewalls of a respective one of the sacrificial pattern layers L21 and a portion of the surface of the second dielectric layer L4.

In operation S53, the fourth mask layer is removed.

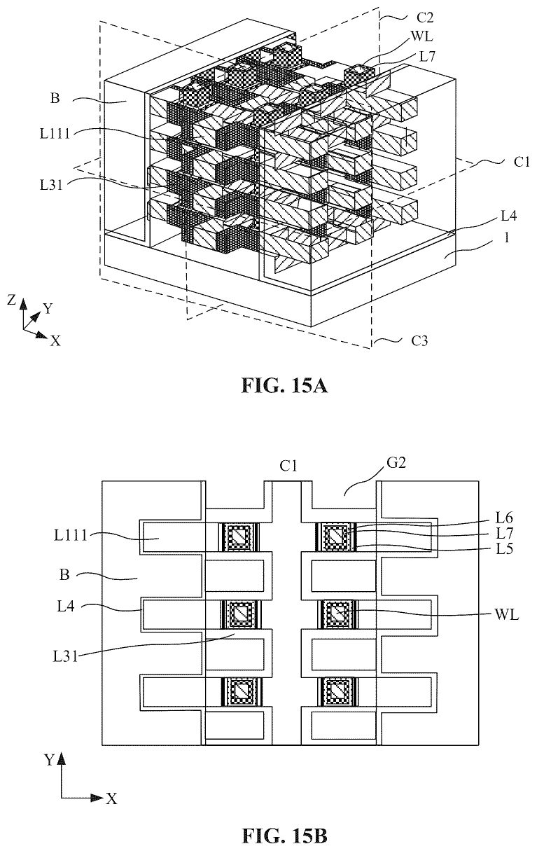

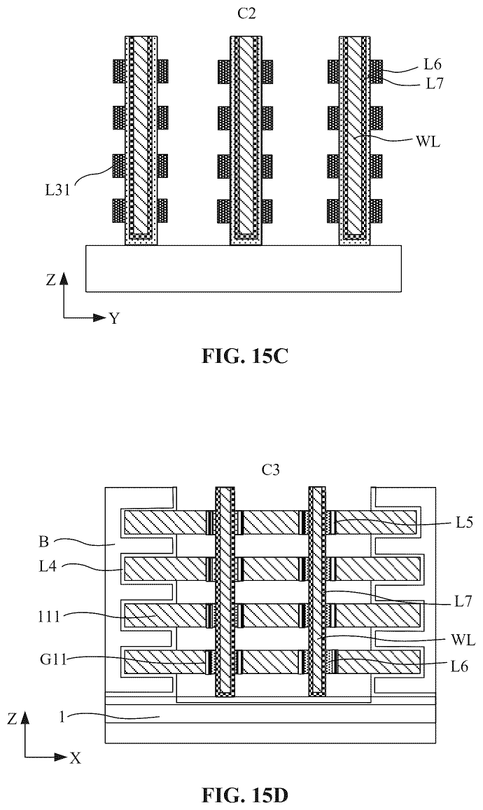

In some embodiments, with reference to FIG. 15A and FIG. 15B, FIG. 15C and FIG. 15D, in operation S60, the sacrificial pattern layers L21 in all areas between adjacent ones of the conductive pattern layers L1 are removed from interior of the through holes, to expose the initial semiconductor layers L6 between the adjacent ones of the conductive pattern layers L1.

Exemplarily, the sacrificial pattern layers L21 are removed by using an isotropic etching process based on the through holes G2 respectively.

In some embodiments, with continuous reference to FIG. 15A and FIG. 15B, FIG. 15C and FIG. 15D, the operation S70 of removing, from interior of the through holes, the initial semiconductor layers L6 between the adjacent ones of the conductive pattern layers L1, to form multiple semiconductor parts that are independent mutually and correspond to the multiple conductive units 111 respectively includes the following operations. Each of the initial semiconductor layers L6 exposed in a respective one of the through holes G2 is isotropically etched by using a respective one of the first dielectric layers L7 as an etching stop layer, to form the semiconductor parts.

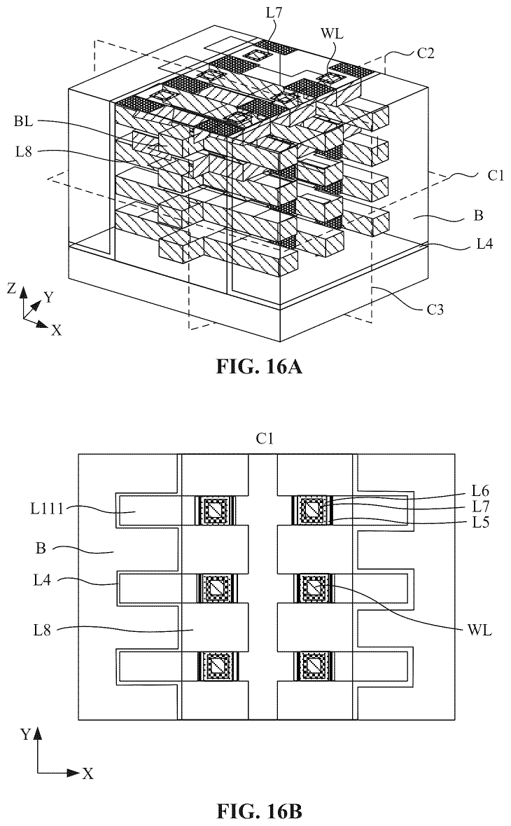

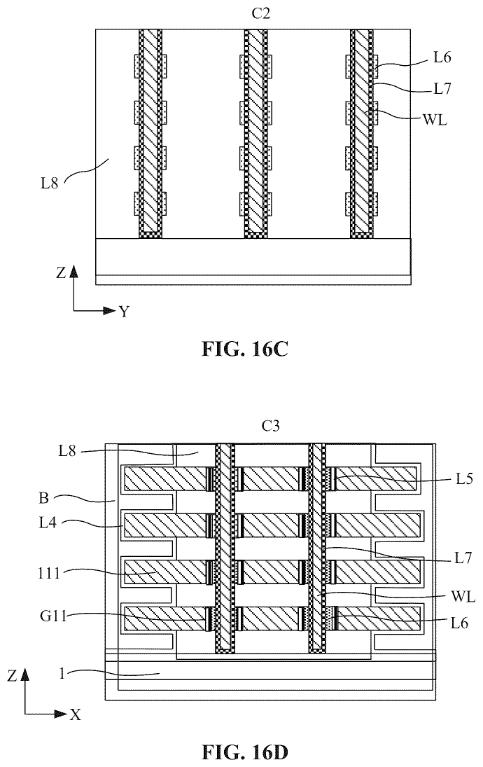

In some embodiments, with reference to FIG. 16A and FIG. 16B, FIG. 16C and FIG. 16D, in operation S80, areas where the sacrificial pattern layers L21 are removed and areas where the initial semiconductor layers L6 are etched, are back-filled with insulation materials respectively, to form second insulation layers L8.

Exemplarily, material of the second insulation layer L8 includes, but is not limited to an oxide, such as a material with a low dielectric constant K, such as silicon oxide, etc.

The material of the first insulation layer may be the same as or different from the material of the second insulation layer, as long as each of them is the material with a low dielectric constant, for example, each of them is a SixOy material with a low dielectric constant K. It may be understood that a ratio of a number of Si atoms to a number of O atoms is not limited here.

Exemplarily, the second insulation layer L8 is formed by using a deposition process.

Some embodiments of the disclosure further provide a memory, with reference to FIG. 5A to FIG. 16D, the memory includes a substrate 1 and multiple conductive layers L111 stacked at intervals in a direction perpendicular to the substrate 1 (such as a Z direction). Each of the conductive layers L111 includes a BL extending along a column direction (such as a Y direction), and multiple conductive units 111 arranged at intervals in the column direction (such as the Y direction); each of the conductive unit includes a first conductive part integrally connected to the BL, and a second conductive part spaced apart from the first conductive part in a row direction (such as an X direction); the row direction (such as the X direction) and the column direction (such as the Y direction) are parallel to the substrate 1, and the row direction intersects with the column direction.

The memory further includes multiple WLs, multiple semiconductor parts, multiple first insulation layers L31, and second insulation layers L8. Each of the multiple WLs extends along the direction perpendicular to the substrate 1 (such as the Z direction) and is disposed between the first conductive part and the second conductive part corresponding to a respective one of the conductive units 111, a sidewall of each of the WLs is covered with a first dielectric layer L7. Each of the multiple semiconductor parts surrounds a respective one of the WLs and is disposed on a surface of a respective one of the first dielectric layers L7 away from the WL and between the first conductive part and the second conductive part corresponding to the respective one of the conductive units 111. Each of the multiple first insulation layers L3 is disposed in a spacing between two adjacent ones of the conductive units 111 in the column direction (such as the Y direction), covers corresponding sidewalls of the first conductive part, the second conductive part and a respective one of the semiconductor parts in the row direction (such as the X direction), and extends to cover sidewalls of the BL disposed in the spacing. Each of the second insulation layers L8 is disposed on upper and lower surfaces of two adjacent ones of the conductive layers, extends to cover sidewalls of a respective one of the first insulation layers L31 exposed in the spacing, and is connected with the respective one of the first insulation layers L31 to form an integrated structure.

In the embodiments of the disclosure, the memory uses the above structure, and technical effects that may be achieved by the memory are the same as technical effects that may be achieved by the method for manufacturing the memory in the foregoing embodiments, which will not be elaborated here.

Exemplarily, the substrate 1 may be made of a semiconductor material, an insulation material, a conductor material, or any combination of material types thereof. The substrate 1 may be a single-layer structure or a multi-layer structure. For example, the substrate 1 may be for example a Si substrate, a SiGe substrate, a SiGeC substrate, a SiC substrate, a GaAs substrate, an InAs substrate, an InP substrate, or other III/V semiconductor substrates or II/VI semiconductor substrates. Or, for another example, the substrate 1 may be a layer-shaped substrate including for example a stack of layers of of Si and SiGe, a stack of layers of of Si and SiC, an SOI, or a silicon germanium on insulator, etc.

Exemplarily, the conductive layer L111 includes a metal layer, such as a tungsten layer.

Exemplarily, material of each of the WL and the BL includes a metal, such as tungsten, or copper, etc.

In some embodiments, an outer boundary of an orthographic projection of each of the semiconductor parts on the substrate 1 includes a rectangular shape. The memory further includes multiple contact layers L5 disposed on sidewalls of the semiconductor parts in the column direction respectively.

Exemplarily, the contact layers L5 include, but are not limited to nitride layers, such as titanium nitride layers. In this way, the contact layers L5 are formed on two etched surfaces of the conductive unit 111 that are exposed in the WL hole G11, and the contact layers L5 (such as the titanium nitride layers) are used as contact structures between the WL holes G11 and the multiple conductive pattern layers L111, to effectively reduce a contact resistance of the memory, thereby further improving performance of the memory.

In some embodiments, the memory further includes multiple storage capacitors; each of the storage capacitors includes a first electrode A, a second dielectric layer L4, and a second electrode B. An end of the second conductive part away from the BL constitutes the first electrode A. The second dielectric layer LA is disposed on upper and lower surfaces and sidewalls of the first electrode A, and extends to cover sidewalls of the first insulation layer L31 and the second insulation layer L8 exposed between the first electrode A and an adjacent first electrode A. The second electrode B is disposed on a surface of the second dielectric layer LA away from the first electrode A.

Exemplarily, material of the second electrode B includes, but is not limited to polysilicon.

Exemplarily, the second dielectric layer LA includes, but is not limited to a HK dielectric layer. The HK dielectric layer refers to a dielectric layer with a high dielectric constant K, and the high dielectric constant K is for example greater than 3.9.

Some embodiments of the disclosure further provide an electronic device, such as a data storage device, a photocopier, a network device, a household appliance, an instrument and a meter, a mobile phone, a computer, or other devices with a data storage function. The electronic device may include a housing, a circuit board arranged in the housing, and a memory integrated on the circuit board. Structure of the memory may refer to relevant descriptions in some of the above embodiments. The electronic device may further include other essential elements or components, which are not limited in the embodiments of the disclosure.

In some embodiments, a processor or an executer or other external control devices coupled to the memory may also be integrated on the circuit board. For example, the electronic device further includes a processor integrated on the circuit board. The processor is coupled to the memory, and the processor may control read and write operations of the memory.

In some embodiments, the memory is a three-dimensional Dynamic Random Access Memory (3D-DRAM).

Technical features of the above embodiments may be combined arbitrarily. In order to make the description concise, all possible combinations of the technical features of the above embodiments are not described. However, combinations of these technical features should be considered as falling within the scope of the specification, as long as there is no conflict therein.

The above embodiments only express several implementations of the disclosure, and they are described relatively specifically and in detail, however, they cannot be understood as limiting the patent scope of the disclosure. It should be pointed out that several modifications and improvements may also be made by those of ordinary skill in the art without departing from the concept of the disclosure, and all of them fall within the scope of protection of the disclosure. Therefore, the patent scope of protection of the disclosure shall be subject to the appended claims.

1. A method for manufacturing a memory, comprising:
forming, along a direction perpendicular to a substrate, a plurality of conductive pattern layers and a plurality of sacrificial pattern layers stacked alternately, wherein each of the conductive pattern layers comprises a Bit Line (BL) extending along a column direction, and a plurality of conductive units integrally connected to the BL and arranged at intervals in the column direction; an orthographic projection of each of the conductive pattern layers on the substrate is disposed within an orthographic projection of a respective one of the sacrificial pattern layers on the substrate, and a gap is provided between an outer boundary of the orthographic projection of each of the conductive pattern layers on the substrate and an outer boundary of the orthographic projection of the respective one of the sacrificial pattern layers on the substrate;
forming initial first insulation layers each covering sidewalls of a respective one of the conductive pattern layers and sidewalls of a respective one of the sacrificial pattern layers, wherein material of the initial first insulation layer is different from material of the sacrificial pattern layer;
forming, along the direction perpendicular to the substrate, Word Line (WL) holes each penetrating the conductive units and the sacrificial pattern layers corresponding thereto, wherein the WL hole in each of the conductive units exposes sidewalls of a respective one of the conductive pattern layers and sidewalls of a respective one of the initial first insulation layers arranged on the a same layer as the respective one of the conductive pattern layers such that each of the conductive units is separated into two independent portions, while exposes a respective one of the sacrificial pattern layers disposed between two adjacent ones of the conductive pattern layers, and the sacrificial pattern layers fully surround respective WL holes;
sequentially forming, on a sidewall of each of the WL holes, an initial semiconductor layer, a first dielectric layer, and a WL covering a surface of the first dielectric layer away from the initial semiconductor layer and filling the WL hole;
etching, along the direction perpendicular to the substrate, the initial first insulation layers in initial first insulation layer areas between two adjacent ones of the conductive units connected to a same BL, to obtain through holes, wherein sidewalls of each of the through holes expose the sacrificial pattern layers, and the initial first insulation layers after being patterned form first insulation layers respectively;
removing, from interior of the through holes, the sacrificial pattern layers in all areas between adjacent ones of the conductive pattern layers, to expose the initial semiconductor layers between the adjacent ones of the conductive pattern layers;
removing, from interior of the through holes, the initial semiconductor layers between the adjacent ones of the conductive pattern layers, to form a plurality of semiconductor parts that are independent mutually and correspond to the plurality of conductive units respectively; and
back-filling, with insulation materials, areas where the sacrificial pattern layers are removed and areas where the initial semiconductor layers are etched respectively.

2. The method for manufacturing a memory of claim 1, further comprising: before sequentially forming, on the sidewall of each of the WL holes, the initial semiconductor layer, the first dielectric layer and the WL covering a the surface of the first dielectric layer away from the initial semiconductor layer and filling the WL hole,
forming contact layers on the sidewalls of the WL holes respectively, wherein each of the contact layers is configured to reduce a contact resistance between a respective one of the conductive units and a respective one of the semiconductor parts, and each of the contact layers is in contact with a respective one of the conductive pattern layers, a respective one of the sacrificial pattern layers and a respective one of the initial first insulation layers simultaneously; and
performing a patterning process on each of the contact layers to reserve an area in contact with the respective one of the conductive pattern layers.

3. The method for manufacturing a memory of claim 2, wherein a distance between two etched surfaces of each sacrificial pattern layer that are exposed in the WL hole and opposite to each other in a row direction is a first distance, and a distance between two etched surfaces of each conductive unit that are exposed in the WL hole is a second distance, and
wherein a thickness of the contact layer is less than or equal to half of a difference between the second distance and the first distance.

4. The method for manufacturing a memory of claim 2, further comprising:
before forming the contact layers on the sidewalls of the WL holes respectively, back-etching each of the conductive pattern layers exposed by the WL holes,
wherein performing the patterning process on each of the contact layers to reserve the area in contact with the respective one of the conductive pattern layers comprises: after forming the contact layers on the sidewalls of the WL holes respectively, removing contact layers in contact with the initial first insulation layers and the sacrificial pattern layers by dry etching in the WL holes.

5. The method for manufacturing a memory of claim 1, wherein forming, along the direction perpendicular to the substrate, the plurality of conductive pattern layers and the plurality of sacrificial pattern layers stacked alternately comprises:
forming, along the direction perpendicular to the substrate, a plurality of conductive material layers and a plurality of sacrificial material layers stacked alternately;
forming a first mask layer above the plurality of conductive material layers and the plurality of sacrificial material layers, wherein the first mask layer is provided with a first pattern, and the first pattern is configured to define areas where the BL and each of the conductive units are formed;
anisotropically etching the plurality of conductive material layers and the plurality of sacrificial material layers, to form a plurality of trenches each penetrating the conductive material layers and the sacrificial material layers, to transfer the first pattern to the conductive material layers and the sacrificial material layers, to form a plurality of initial conductive pattern layers and the plurality of sacrificial pattern layers stacked alternately;
removing the first mask layer; and
back-etching each of the initial conductive pattern layers in a respective one of the trenches by using an isotropic etching process, to form the plurality of conductive pattern

6. The method for manufacturing a memory of claim 1, wherein material of the first insulation layers is different from the material of the sacrificial pattern layer, and the first insulation layers and the sacrificial pattern layer have different etching selectivity ratios.

7. The method for manufacturing a memory of claim 1, wherein material of the first insulation layers comprises silicon oxide, and the material of the sacrificial pattern layer comprises silicon nitride, aluminum oxide or polysilicon.

8. The method for manufacturing a memory of claim 1, further comprising: before forming, along the direction perpendicular to the substrate, the WL holes each penetrating the conductive units and the sacrificial pattern layers corresponding thereto,
forming a second mask layer above the initial first insulation layers, the plurality of conductive pattern layers and the plurality of sacrificial pattern layers, wherein the second mask layer is provided with a first opening pattern, and the first opening pattern is configured to define an area where a storage capacitor is formed;
removing portions of the initial first insulation layers and portions of the sacrificial pattern layers based on the first opening pattern, to expose an end of each of the conductive units away from the BL, wherein the ends constitute a first electrode of the storage capacitor;
depositing a dielectric material on upper and lower surfaces and sidewalls of the first electrode, to form a second dielectric layer; and
depositing a conductive material on a surface of the second dielectric layer away from the first electrode to form a second electrode of the storage capacitor.

9. The method for manufacturing a memory of claim 8, wherein depositing the conductive material on the surface of the second dielectric layer away from the first electrode to form the second electrode of the storage capacitor further comprises:
depositing the conductive material on the surface of the second dielectric layer away from the first electrode, to form a second electrode material layer; and
grinding the second electrode material layer with a top one of the sacrificial pattern layers as a grinding stop layer, and removing the second mask layer simultaneously, to form the second electrode.

10. The method for manufacturing a memory of claim 8, wherein removing the portions of the initial first insulation layers and the portions of the sacrificial pattern layers based on the first opening pattern comprises:
removing the portions of the initial first insulation layers based on the first opening pattern; and
isotropically etching the sacrificial pattern layers based on the first opening pattern, to remove the sacrificial pattern layers below the first opening pattern.

11. The method for manufacturing a memory of claim 8, wherein after the second electrode of the storage capacitor is formed, forming, along the direction perpendicular to the substrate, the WL holes each penetrating the conductive units and the sacrificial pattern layers corresponding thereto comprises:
forming a third mask layer above the second electrode, the initial first insulation layers, the plurality of conductive pattern layers and the plurality of sacrificial pattern layers, wherein the third mask layer is provided with a second opening pattern, and the second opening pattern is configured to define areas where the WLs are formed;
etching the plurality of conductive pattern layers and the plurality of sacrificial pattern layers based on the second opening pattern, to form WL initial accommodation grooves;
removing the third mask layer; and
back-etching surfaces of each of the conductive units exposed in a respective one of the WL initial accommodation grooves by using an isotropic etching process, to form a respective one of the WL holes.

12. The method for manufacturing a memory of claim 8, wherein etching, along the direction perpendicular to the substrate, the initial first insulation layers in initial first insulation layer areas between two adjacent ones of the conductive units connected to a same BL to obtain the through holes comprises:
forming a fourth mask layer above the second electrode, the initial first insulation layers, the plurality of conductive pattern layers and the plurality of sacrificial pattern layers, wherein the fourth mask layer is provided with a third opening pattern, and the third opening pattern is configured to define areas where the initial first insulation layers are removed;
removing the initial first insulation layers on sidewalls of the sacrificial pattern layers respectively based on the third opening pattern, to form the through holes, wherein each of the through holes exposes a portion of sidewalls of a respective one of the sacrificial pattern layers and a portion of the surface of the second dielectric layer; and
removing the fourth mask layer.

13. The method for manufacturing a memory of claim 8, wherein the sacrificial pattern layers are removed by using an isotropic etching process based on the through holes respectively,
removing, from interior of the through holes, the initial semiconductor layers between the adjacent ones of the conductive pattern layers, to form the plurality of semiconductor parts that are independent mutually and correspond to the plurality of conductive units respectively comprises: isotropically etching each of the initial semiconductor layers exposed in a respective one of the through holes by using a respective one of the first dielectric layers as an etching stop layer, to form the semiconductor parts.

14. A memory, comprising: a substrate and a plurality of conductive layers stacked at intervals in a direction perpendicular to the substrate, wherein each of the conductive layers comprises a Bit Line (BL) extending along a column direction, and a plurality of conductive units arranged at intervals in the column direction; each of the conductive unit comprises a first conductive part integrally connected to the BL, and a second conductive part spaced apart from the first conductive part in a row direction; the row direction and the column direction are parallel to the substrate, and the row direction intersects with the column direction, and
wherein the memory further comprises:
a plurality of Word Lines (WLs), each of which extends along the direction perpendicular to the substrate and is disposed between the first conductive part and the second conductive part corresponding to a respective one of the conductive units, wherein a sidewall of each of the WLs is covered with a first dielectric layer;
a plurality of semiconductor parts, each of which surrounds a respective one of the WLs, and each of which is disposed on a surface of a respective one of the first dielectric layers away from the WL, and between the first conductive part and the second conductive part corresponding to the respective one of the conductive units;
a plurality of first insulation layers, each of which is disposed in a spacing between two adjacent ones of the conductive units in the column direction, covers corresponding sidewalls of the first conductive part, the second conductive part and a respective one of the semiconductor parts in the row direction, and extends to cover sidewalls of the BL disposed in the spacing; and
second insulation layers, each of which is disposed on upper and lower surfaces of two adjacent ones of the conductive layers, extends to cover sidewalls of a respective one of the first insulation layers exposed in the spacing, and is connected with the respective one of the first insulation layers to form an integrated structure.

15. The memory of claim 14, further comprising: contact layers each disposed between a respective one of the semiconductor parts and the first conductive part, and contact layers each disposed between the respective one of the semiconductor parts and the second conductive part, wherein a work function of the contact layer is comprised between a work function of the conductive unit and a work function of the semiconductor part.

16. The memory of claim 15, wherein material of the contact layer comprises titanium, titanium nitride, thallium or thallium nitride, material of each of the first conductive part and the second conductive part comprises tungsten, and material of the semiconductor part is metal oxide semiconductor.

17. An electronic device, comprising a memory that comprises: a substrate and a plurality of conductive layers stacked at intervals in a direction perpendicular to the substrate, wherein each of the conductive layers comprises a Bit Line (BL) extending along a column direction, and a plurality of conductive units arranged at intervals in the column direction; each of the conductive unit comprises a first conductive part integrally connected to the BL, and a second conductive part spaced apart from the first conductive part in a row direction; the row direction and the column direction are parallel to the substrate, and the row direction intersects with the column direction, and
wherein the memory further comprises:
a plurality of Word Lines (WLs), each of which extends along the direction perpendicular to the substrate and is disposed between the first conductive part and the second conductive part corresponding to a respective one of the conductive units, wherein a sidewall of each of the WLs is covered with a first dielectric layer;
a plurality of semiconductor parts, each of which surrounds a respective one of the WLs, and each of which is disposed on a surface of a respective one of the first dielectric layers away from the WL, and between the first conductive part and the second conductive part corresponding to the respective one of the conductive units;
a plurality of first insulation layers, each of which is disposed in a spacing between two adjacent ones of the conductive units in the column direction, covers corresponding sidewalls of the first conductive part, the second conductive part and a respective one of the semiconductor parts in the row direction, and extends to cover sidewalls of the BL disposed in the spacing; and
second insulation layers, each of which is disposed on upper and lower surfaces of two adjacent ones of the conductive layers, extends to cover sidewalls of a respective one of the first insulation layers exposed in the spacing, and is connected with the respective one of the first insulation layers to form an integrated structure.

18. The electronic device of claim 17, wherein the memory further comprises:
contact layers each disposed between a respective one of the semiconductor parts and the first conductive part, and contact layers each disposed between the respective one of the semiconductor parts and the second conductive part, wherein a work function of the contact layer is comprised between a work function of the conductive unit and a work function of the semiconductor part.

19. The electronic device of claim 18, wherein material of the contact layer comprises titanium, titanium nitride, thallium or thallium nitride, material of each of the first conductive part and the second conductive part comprises tungsten, and material of the semiconductor part is metal oxide semiconductor.
